(19) United States
(12) Patent Application Publication
(10) Pub. No.: US 2016/0268303 A1
(43) Pub. Date: Sep. 15, 2016

(54) SEMICONDUCTOR MEMORY DEVICE AND METHOD FOR MANUFACTURING SAME

(71) Applicant: Kabushiki Kaisha Toshiba, Minato-ku (JP)

(72) Inventors: Tomoya KAWAI, Kawasaki (JP); Yoshiaki FUKUZUMI, Yokkaichi (JP); Hideaki AOCHI, Yokkaichi (JP)

(73) Assignee: Kabushiki Kaisha Toshiba, Minato-ku (JP)

(21) Appl. No.: 15/041,163

(22) Filed: Feb. 11, 2016

Related U.S. Application Data
(60) Provisional application No. 62/132,986, filed on Mar. 13, 2015.

(51) Int. Cl. H01L 27/115; H01L 21/3205; H01L 21/28

(52) U.S. Cl. CPC H01L 27/11582; H01L 27/1157; H01L 21/28282; H01L 21/32053

(57) ABSTRACT

According to one embodiment, a method for manufacturing a semiconductor memory device includes forming a first stacked portion on a conductive layer, the first stacked portion including a plurality of first layers and a plurality of second layers; forming a first slit; forming a sacrificial film in the first slit; forming a second stacked portion on the first stacked portion and the sacrificial film; forming a second slit; removing the sacrificial film; embedding a separation film; forming a select gate; forming a hole; forming a film including a charge storage film, on an inner wall of the hole; and forming a channel body on an inner side of the film including the charge storage film. The second stacked portion includes the plurality of first layers and the plurality of second layers, the first layers is separately stacked each other, the second layers is provided between the first layers.

### CROSS-REFERENCE TO RELATED APPLICATIONS

This application is based upon and claims the benefit of priority from U.S. Provisional Patent Application No. 62/132,986 filed on Mar. 13, 2015; the entire contents of which are incorporated herein by reference.

### FIELD

Embodiments described herein relate generally to a semiconductor memory device and a method for manufacturing same.

### BACKGROUND

Memory devices having a three-dimensional structure in which electrode layers function as control gates in each memory cell have been proposed. In these memory devices, a plurality of electrode layers is formed separated by insulating layers. Memory holes are formed in the resulting stacked body, and silicon bodies that serve as channels are formed along the sidewalls of the memory holes with charge storage films disposed therebetween.

On the stacked body including a plurality of electrode layers and a plurality of insulating layers in such a three-dimensional device, a slit is formed by reactive ion etching (RIE), for example.

In this case, as the number of layers of the stacked body increases, higher shape controllability and size controllability of the slit are desired.

### BRIEF DESCRIPTION OF THE DRAWINGS

FIG. 1 is a schematic perspective view of a memory cell array of an embodiment;

FIGS. 2A and 2B are schematic cross-sectional views of the memory strings of the embodiment;

FIG. 3A is an enlarged schematic cross-sectional view a part of the column of the embodiment and FIG. 3B is an enlarged schematic cross-sectional view a part of the separator of the embodiment;

FIG. 4A to FIG. 6B are schematic cross-sectional views showing a method for manufacturing the semiconductor memory device of the embodiment;

FIG. 7A to FIG. 8 are schematic cross-sectional views showing a method for manufacturing the semiconductor memory device of another embodiment;

FIG. 9A to FIG. 10C are schematic cross-sectional views showing a method for manufacturing the semiconductor memory device of further another embodiment;

FIG. 11 is a schematic perspective view of a memory cell array of another embodiment;

FIG. 12 is a schematic perspective view of a memory cell array of further another embodiment; and

FIG. 13 is an enlarged schematic cross-sectional view a part of the separator of the embodiment.

### DETAILED DESCRIPTION

According to one embodiment, a method for manufacturing a semiconductor memory device includes forming a first stacked portion on a conductive layer, the first stacked portion including a plurality of first layers and a plurality of second layers, the first layers separately stacked each other, the second layers provided between the first layers; forming a first slit piercing the first stacked portion in a stacking direction of the first stacked portion; forming a sacrificial film in the first slit; forming a second stacked portion on the first stacked portion and the sacrificial film; forming a second slit piercing the second stacked portion to reach the sacrificial film; removing the sacrificial film through the second slit;

embedding a separation film into the first slit and the second slit; forming a select gate on the second stacked portion; and forming a plurality of memory cells in the first stacked portion and the second stacked portion, the forming the memory cells including forming a hole piercing from the select gate to the first stacked portion, forming a film including a charge storage film, on an inner wall of the hole, and forming a channel body on an inner side of the film including the charge storage film. The second stacked portion includes the plurality of first layers and the plurality of second layers, the first layers is separately stacked each other, the second layers is provided between the first layers.

Embodiments will be described below with reference to drawings. Note that the same reference numerals are applied for the same elements in each drawing.

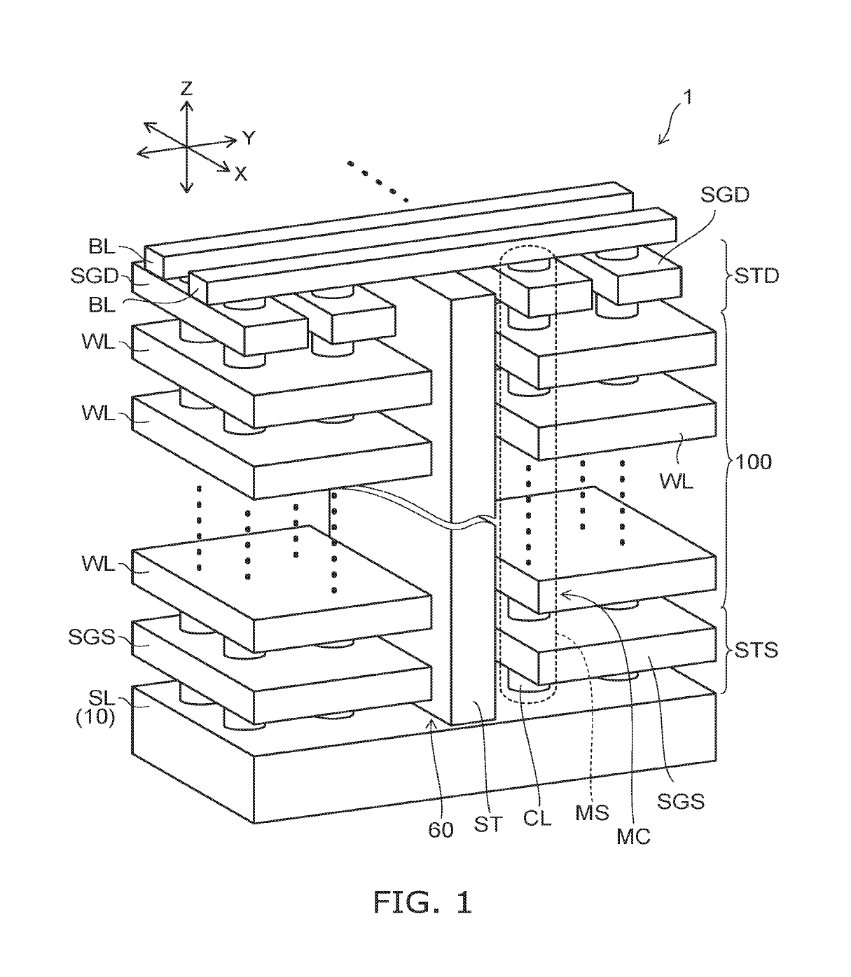

FIG. 1 is a perspective view schematically illustrating a memory cell array 1 according to an embodiment. For simplicity, elements such as insulating layers between electrode layers are not illustrated in FIG. 1.

In FIG. 1, two directions orthogonal to each other are an X direction and a Y direction. Another direction orthogonal to the X direction and the Y direction (XY plane) is a Z direction (stacking direction), in which a plurality of electrode layers WL are stacked.

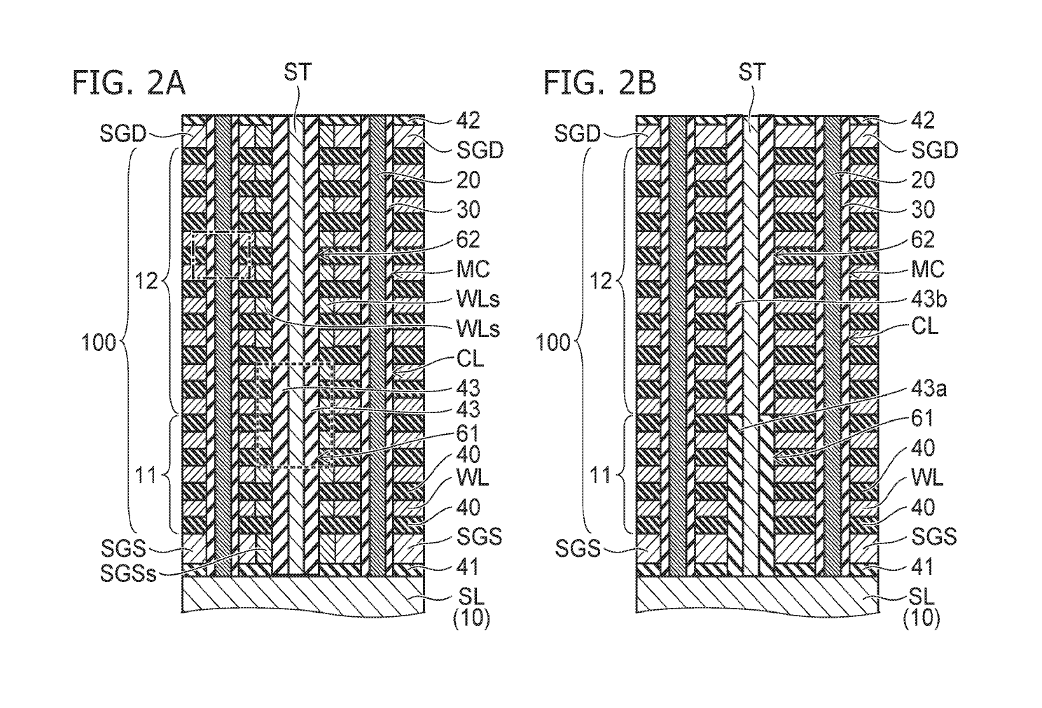

FIG. 2A and FIG. 2B are cross-sectional views schematically illustrating memory strings MS. FIG. 2A and FIG. 2B illustrate cross sections parallel to the YZ plane in FIG. 1. Note that in FIG. 2A and FIG. 2B, portions upper than a drain-side select gate SGD in FIG. 1 are omitted.

As illustrated in FIG. 1, the memory cell array 1 includes a plurality of memory strings MS.

A substrate 10 has a conductive layer SL. The substrate 10 and the conductive layer SL include, for example, silicon. A source-side select gate SGS is provided on the conductive layer SL with an insulating layer 41 disposed therebetween. An insulating layer 40 is provided on the source-side select gate SGS. The stacked body 100 is provided on the insulating layer 40. The stacked body 100 includes a plurality of electrode layers WL (first layers) and a plurality of insulating layers 40 (second layers). The plurality of electrode layers WL is separately stacked each other, and the plurality of insulating layers 40 is provided between the plurality of electrode layers WL. The plurality of electrode layers WL and the plurality of insulating layers 40 are, for example, alternately stacked. The number of the electrode layers WL illustrated in the drawings is an example, and the number of the electrode layers WL may be arbitrary.

Another insulating layer 40 is provided on the topmost electrode layer WL, and the drain-side select gate SGD is provided on the insulating layer 40.

The source-side select gate SGS, the drain-side select gate SGD, and the electrode layer WL are silicon layers containing silicon as a major component, and the silicon layers are doped with, for example, boron as impurities for imparting conductivity. Moreover, the source-side select gate SGS, the drain-side select gate SGD, and the electrode layer WL may contain, for example, metal (e.g., tungsten), and may contain at least one of metal and metal silicide. An insulating film mainly containing silicon oxide, for example, is used for the insulating layer 40.

The drain-side select gate SGD and the source-side select gate SGS are thicker than a single electrode layer WL, and pluralities of drain-side select gates SGD and source-side select gates SGS may be provided, for example, with primary purpose of improving cut-off characteristic of select transistor.

Columns CL are provided in the stacked body 100, the source-side select gate SGS and the drain-side select gate SGD, and the columns extend in the Z direction. The column CL extends through the stacked body 100, the source-side select gate SGS and the drain-side select gate SGD. The column CL has columnar or elliptic columnar, for example. The column CL is electrically connected with the conductive layer SL.

A separator 60 provided in the stacked body 100 and the source-side select gate SGS, and the separator 60 extends in the X direction. An insulating film 43 is provided on a sidewall of the separator 60. An intermediate layer ST, for example, is provided on an inner side of the insulating film 43, and a side surface of the intermediate layer ST is covered with the insulating film 43. For example, a material (e.g., tungsten) having conductivity is used for the intermediate layer ST, and the intermediate layer ST is electrically connected with the conductive layer SL.

The bottom end of the intermediate layer ST is electrically connected with a channel body 20 of the column CL through the conductive layer SL. The top end of the intermediate layer ST is electrically connected with a peripheral circuit through wiring (not illustrated).

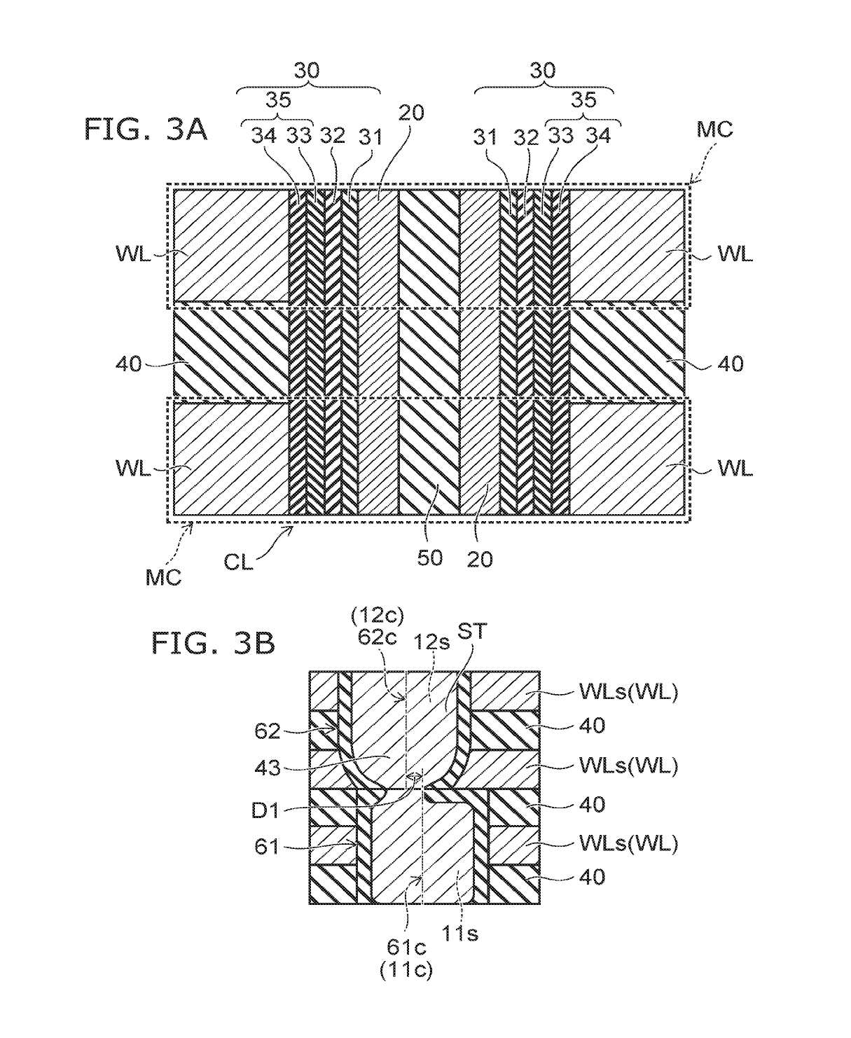

FIG. 3A is an enlarged cross-sectional view schematically illustrating a portion of the column CL of the embodiment. FIG. 3A is a schematic cross-sectional view of the long dashed short dashed line portion of FIG. 2A.

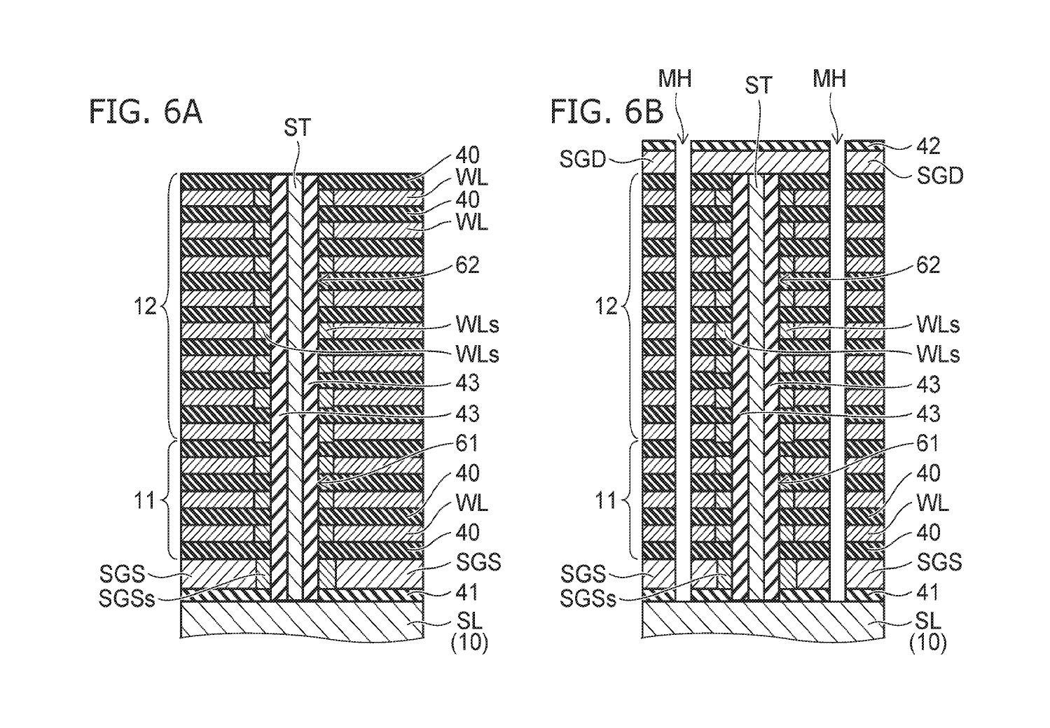

The column CL is formed in a memory hole MH (FIG. 6B) formed in the stacked body 100. In the memory hole MH, the channel body 20 as a semiconductor channel is provided. The channel body 20 is a single crystalline silicon film or a polycrystalline silicon film containing silicon as a major component, for example.

The channel body 20 is provided to have a columnar shape extending in the stacking direction of the stacked body 100. The top end of the channel body 20 is connected to a bit line BL (wiring) illustrated in FIG. 1, and the bottom end of the channel body 20 is connected to the conductive layer SL. Each bit line BL extends in the Y direction.

A memory film 30 is provided between the electrode layer WL and the channel body 20. The memory film 30 includes a block insulating film 35, a charge storage film 32, and a tunnel insulating film 31.

Between the electrode layer WL and the channel body 20, the block insulating film 35, the charge storage film 32, and the tunnel insulating film 31 are provided in this order from the electrode layer WL side. The block insulating film 35 is in contact with the electrode layer WL, and the tunnel insulating film 31 is in contact with the channel body 20. The charge storage film 32 is provided between the block insulating film 35 and the tunnel insulating film 31. For example, the charge storage film 32 may include a plurality of charge storage portions, the charge storage portions may be separately stacked each other via the insulating layer 40.

The electrode layer WL surrounds the channel body 20 with the memory film 30 disposed therebetween. A core insulating film 50 is provided on the inner side of the channel body 20.

The channel body 20 functions as a semiconductor channel in the memory cell MC, and the electrode layer WL functions as a control gate of the memory cell MC. The charge storage film 32 functions as a data memory layer storing electric charge injected from the channel body 20. In other words, the memory cell having a control gate surrounding the channel therein is formed at the location where the channel body 20 and each electrode layer WL intersect.

The semiconductor memory device of the embodiment can electrically and freely delete and write data, and can retain memory contents even after the power supply is turned off.

The memory cell MC is of a charge trap type, for example. The charge storage film 32 includes a number of trapping sites for trapping electric charge, and is a silicon nitride film, for example.

The tunnel insulating film 31 serves as a potential barrier when electric charge is injected to the charge storage film 32 from the channel body 20 or when electric charge stored in the charge storage film 32 is released to the channel body 20. The tunnel insulating film 31 is a silicon oxide film, for example.

Alternatively, the tunnel insulating film 31 may include a stacked film (ONO film), the stacked film includes a silicon nitride film interposed between a pair of silicon oxide films. When the ONO film is used for the tunnel insulating film 31, the erasing operation can be performed in a lower electric field than when a single-layer silicon oxide film is used.

The block insulating film 35 prevents electric charge stored in the charge storage film 32 from releasing to the electrode layer WL. The block insulating film 35 includes a cap film 34 provided in contact with the electrode layer WL and a block film 33 provided between the cap film 34 and the charge storage film 32.

The block film 33 is a silicon oxide film, for example. The cap film 34 has a higher permittivity than silicon oxide, and is a silicon nitride film, for example. Forming this cap film 34 in contact with the electrode layer WL can suppress back-tunneling of electrons injected from the electrode layer WL during erasing. In other words, using a stacked film that includes a silicon oxide film and a silicon nitride film for the block insulating film 35 can enhance the electric charge blocking effect of the block insulating film 35.

When data is written in the memory cell MC, a writing potential Vprog (e.g., approximately 20 V) is applied to the electrode layer WL of the memory cell MC in which the data is to be written. A pass potential (or an intermediate potential) Vpass (e.g., approximately 10 V) lower than Vprog is applied to the electrode layer WL of the memory cell MC in which the data is not to be written. In this manner, the electric field intensity applied to the tunnel insulating film 31 is increased only in the memory cell MC in which the data is to be written, and the electron is injected to the charge storage film 32 from the channel body 20.

As illustrated in FIG. 1, a drain-side select transistor STD is provided at the top end of the column CL in the memory string MS, and a source-side select transistor STS is provided at the bottom end thereof.

The memory cell MC, the drain-side select transistor STD, and the source-side select transistor STS are vertical transistors in which a current flows in the stacking direction of the stacked body 100 (Z direction).

The drain-side select gate SGD functions as a gate electrode (control gate) of the drain-side select transistor STD. An insulating film that functions as a gate insulating film for the drain-side select transistor STD is formed between the drain-side select gate SGD and the channel body 20.

The source-side select gate SGS functions as a gate electrode (control gate) of the source-side select transistor STS. An insulating film that functions as a gate insulating film for the source-side select transistor STS is formed between the source-side select gate SGS and the channel body 20.

A plurality of memory cells MC are provided between the drain-side select transistor STD and the source-side select transistor STS with the electrode layer WL of each layer as the control gate.

Such a plurality of memory cells MC, drain-side select transistor STD, and source-side select transistor STS are connected in series via the channel body 20, and form a single memory string MS. This memory string MS is arrayed in plurality in the X direction and the Y direction, and therefore, a plurality of memory cells is three dimensionally provided in the X direction, Y direction, and Z direction.

As illustrated in FIG. 2A and FIG. 2B, the stacked body 100 includes a first stacked portion 11 and a second stacked portion 12. The second stacked portion 12 is provided on the first stacked portion 11. The separator 60 includes a first separator 61 and a second separator 62.

The first separator 61 is provided in the first stacked portion 11 and extends in the stacking direction. The second separator 62 is provided in the second stacked portion 12 and extends in the stacking direction.

The insulating film 43 is continuously provided in the first separator 61 and the second separator 62. The second separator 62 is in contact with the first separator 61. That is, the first separator 61 is integrally provided with the second separator 62. The intermediate layer ST, for example, may be provided on the inner side of the insulating film 43.

A metal silicide portion WLs (first metal silicide portion, second metal silicide portion) of the electrode layer WL is provided between the first separator 61 and the electrode layer WL and between the second separator 62 and the electrode layer WL. A metal silicide portion SGSs of the source-side select gate SGS is provided between the first separator 61 and the source-side select gate SGS.

In another example, metal (e.g., tungsten) is used for the electrode layer WL. In this case, the metal silicide portion WLs of the electrode layer WL is not provided between the first separator 61 and the electrode layer WL nor between the second separator 62 and the electrode layer WL, as illustrated in FIG. 2B. The insulating films 43 embedded in the first separator 61 and the second separator 62 may be formed from materials different from each other. In this case, for the first separator 61, for example, a film (first film 43a) is used which is formed from a material having a high selectivity (resistance) with respect to etching of the electrode layer WL and the insulating layer 40. For the second separator 62, a film (second film 43b) is used which is formed from a material that is easily embedded into a slit having a high aspect ratio.

FIG. 3B is a schematic cross-sectional view of the broken line portion of FIG. 2A.

As illustrated in FIG. 3B, the width of the bottom surface side of the second separator 62 is not more than the width of the top surface of the first separator 61, and the width of the top surface side of the second separator 62. The distance D1 is between the center 61c of the width of the first separator 61 and the center 62c of the width of the second separator 62, and the distance D1 is, for example, not more than half the width of the first separator 61.

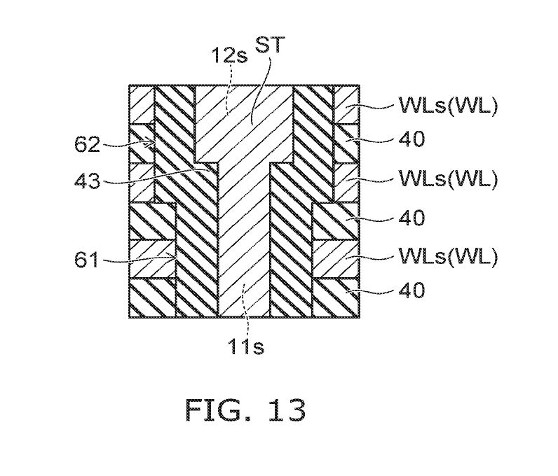

Note that, as illustrated in FIG. 13, for example, the width of the bottom surface side of the second separator 62 is wider than the width of the top surface side of the first separator 61. The width of the bottom surface side of the second separator 62 may be substantially equal to the width of the top surface side thereof. The cross section of the vicinity of the border between the first separator 61 and the second separator 62 is, for example, formed in a T-shape.

According to this embodiment, the slit constituting the separator 60 in the stacked body 100 is formed so as to be divided into a first slit 11s and a second slit 12s. When the second slit 12s is formed, in the first slit 11s, a film is used which is formed from a material having a high selectivity with respect to dry etching of the electrode layer WL and the insulating layer 40. In this manner, it is possible to reduce difficulty of the process for forming the slit.

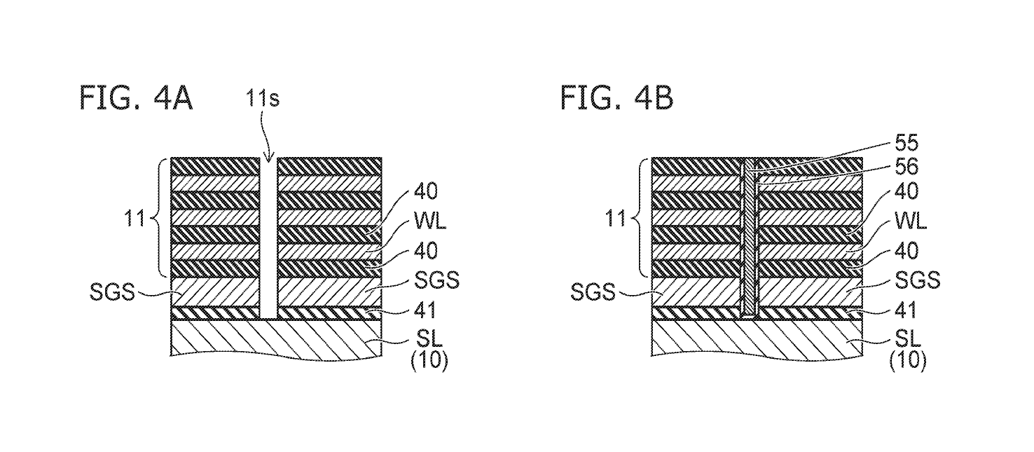

Next, a method for manufacturing a semiconductor memory device of the embodiment will be described with reference to FIG. 4A to FIG. 6B.

As illustrated in FIG. 4A, the source-side select gate SGS is formed on the conductive layer SL with the insulating layer 41 disposed therebetween. The first stacked portion 11 is formed on the source-side select gate SGS. The first stacked portion 11 includes the insulating layers 40 and the electrode layers WL, the electrode layers WL are separately stacked each other, and the insulating layers 40 are provided between the electrode layers WL. The electrode layers WL and the insulating layers 40 are, for example, alternately stacked.

The first slit 11s is formed in the first stacked portion 11. The first slit 11s pierces the first stacked portion 11 in the stacking direction. The first slit 11s is formed by RIE using a mask (not illustrated), for example. The electrode layer WL and the source-side select gate SGS are each exposed on a sidewall of the first slit 11s.

As illustrated in FIG. 4B, an intermediate film 56 is formed on an inner wall of the first slit 11s. A sacrificial film 55 is formed on the inner side of the intermediate film 56. The sacrificial film 55 is embedded in the first slit 11s. A side surface of the intermediate film 56 is in contact with each of the electrode layer WL and the source-side select gate SGS. The intermediate film 56 and the sacrificial film 55 formed on the first stacked portion 11 are removed by chemical mechanical polish (CMP), for example.

The intermediate film 56 prevents metal contained in the sacrificial film 55 from diffusing to the first stacked portion 11.

For the intermediate film 56, at least one of a tungsten nitride film or a titanium nitride film is used.

For the sacrificial film 55, a material, such as tungsten, is used which has a high selectivity with respect to etching of the electrode layer WL and the insulating layer 40.

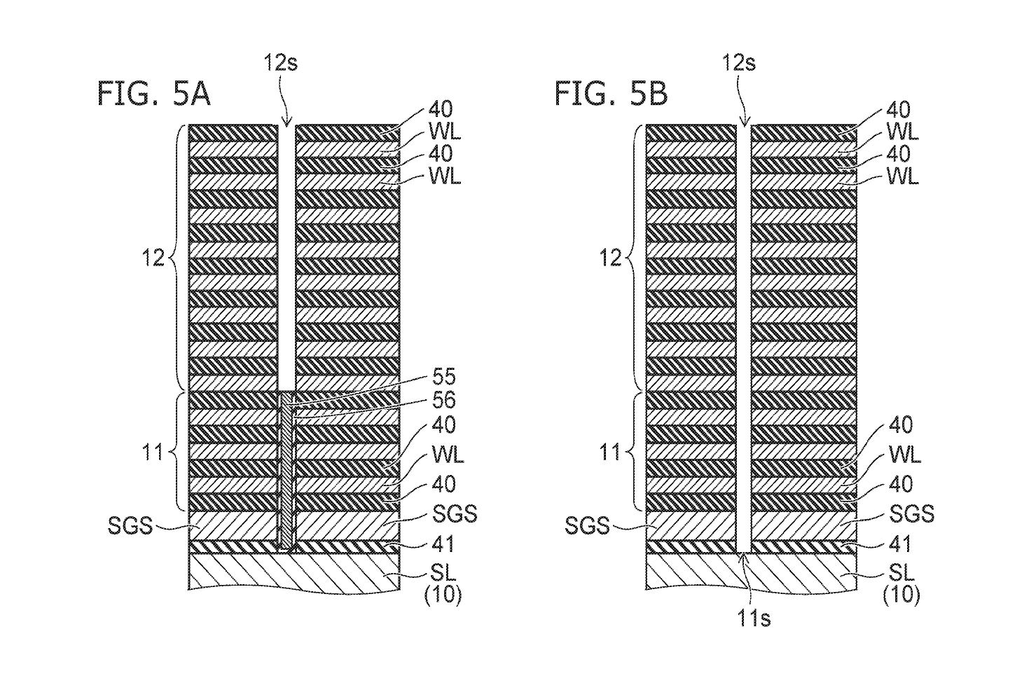

As illustrated in FIG. 5A, the second stacked portion 12 is formed on the first stacked portion 11. The second stacked portion 12 includes the electrode layers WL and the insulating layers, the electrode layers WL are separately stacked each other, and the insulating layers 40 are provided between the electrode layers WL. The electrode layers WL and the insulating layers 40 are, for example, alternately stacked, similarly to the first stacked portion 11.

The second slit 12s is formed in the second stacked portion 12. The second slit 12s pierces the second stacked portion 12 to reach the sacrificial film 55 and the intermediate film 56. The second slit 12s is formed by RIE using a mask (not illustrated), for example. Here, the sacrificial film 55 is used as an etching stopper film. The top surfaces of the sacrificial film 55 and the intermediate film 56 are exposed on the bottom surface of the second slit 12s.

Here, as illustrated in FIG. 3B, the width of the bottom surface side of the second slit 12s is not more than the width of the top surface of the first slit 11s, and the width of the top surface side of the second slit 12s. The distance D1 is between the center 11c of the width of the first slit 11s and the center 12c of the width of the second slit 12s, and the distance D1 is not more than half the width of the first slit 11s.

Furthermore, the sacrificial film 55 has the high selectivity with respect to etching of the electrode layer WL and the insulating layer 40; over etching of second slit 12s can be available. Thus, a taper angle of the second slit 12s can be controlled by adjusting the amount of over etching in RIE. For example, the width of the bottom surface side of the second slit 12s may be substantially equal to the width of the top surface side thereof. The side surface of the second slit 12s can be made substantially perpendicular to a major surface of the conductive layer SL. Over etching after the second slit 12s reaches the sacrificial film 55 causes the width of the second slit 12s to be wider than the width of the first slit 11s, as illustrated in FIG. 13.

As illustrated in FIG. 5B, the sacrificial film 55 and the intermediate film 56 are completely removed by etching through the second slit 12s. Thus, the first slit 11s and the second slit 12s are integrally formed. The top surface of the conductive layer SL is exposed on the bottom surface of the first slit 11s.

Thereafter, there are formed the metal silicide portion WLs of the electrode layer WL and the metal silicide portion SGSs of the source-side select gate SGS. A metal film (e.g., nickel) is formed conformally on sidewalls of the first slit 11s and the second slit 12s, and is annealed at a high temperature. Thus, silicon contained in the electrode layer WL and the source-side select gate SGS reacts with the metal (e.g., nickel), and the metal silicide portion WLs and the metal silicide portion SGSs (e.g., nickel silicide) are formed on the electrode layer WL and the source-side select gate SGS, respectively, that are adjacent to the first slit 11s and the second slit 12s. In this manner, the resistance of the electrode layer WL and the source side select gate SGS is reduced. Thereafter, an excess unreacted metal (nickel) film is removed using a chemical solution containing sulfuric acid, for example.

As illustrated in FIG. 6A, the insulating film 43 is formed on the inner walls of the first slit 11s and the second slit 12s. The intermediate layer ST illustrated in FIG. 3B is formed inner side of the insulating film 43. In this manner, the first separator 61 and the second separator 62 are integrally formed.

For the insulating film 43, a silicon nitride film is used, for example. The metal silicide portion WLs of the electrode layer WL and the metal silicide portion SGSs of the source-side select gate SGS are each covered with the insulating film 43. For the intermediate layer ST, tungsten is used, for example.

As illustrated in FIG. 6B, the drain-side select gate SGD is formed on the second stacked portion 12 with the insulating layer 40 disposed therebetween. An insulating layer 42 is formed on the drain-side select gate SGD.

Thereafter, the memory hole MH is formed piercing the insulating layer 42, the drain-side select gate SGD, the second stacked portion 12, and the first stacked portion 11 to reach the conductive layer SL.

Subsequently, each of the films illustrated in FIG. 3A (memory film 30, channel body 20, and the like) is formed on the inner wall of the memory hole MH. Each of the films extends from the drain-side select gate SGD to the lower position of the first stacked portion 11.

Thereafter, a slit extending through the insulating layer 42 and the drain-side select gate SGD to the insulating film 43, and the metal silicide portion SGDs of the drain-side select gate SGD are formed. After the metal silicide portion SGDs of the drain-side select gate SGD is formed, the insulating film 43 and the intermediate layer ST are embedded in the inner wall of the slit, as illustrated in FIG. 2A.

Then, the bit lines BL and the like are formed on the insulating layer 42. In this manner, the semiconductor memory device of this embodiment is obtained.

For example, when the number of layers of the stacked body increases, an aspect ratio when forming the slit also increases. Thus, the shape control and the size control of the slit become difficult.

Whereas, according to this embodiment, the slit constituting the separator is formed so as to be divided into the first slit 11s and the second slit 12s. This suppresses the increase in the aspect ratio when the slit is formed, and facilitates the shape control and the size control of the slit. That is, even when the number of layers of the stacked body is increased, it is possible to reduce difficulty when the slit is formed.

For example, when a slit having a high aspect ratio is formed in a stacked body, the width of the bottom surface side of the slit tends to be smaller than the width of the top surface side thereof. That is, the side surface of the slit tends to be tapered. Therefore, the width of the bottom surface side of the slit becomes narrow, making it difficult to conformally form a metal film with a uniform film thickness on the inner wall of the slit. It becomes difficult for the metal film to be formed on the bottom surface side of the slit. Thus, when the annealing of the metal silicide processing is performed, the amount of metal diffused to the electrode layer WL on the bottom surface side of the slit tends to be less than the amount of metal diffused to the electrode layer WL on the top surface side thereof.

Whereas, according to this embodiment, the width of the bottom surface side of the second slit 12s can be increased. Thus, the width of the bottom surface side of the second slit 12s is substantially equal to the width of the top surface side thereof. Therefore, it becomes easy to conformally form a metal film with a uniform film thickness on the inner wall of the second slit 12s. Therefore, when the annealing of the metal silicide processing is performed, the amount of metal diffused to the electrode layer WL on the bottom surface side of the second slit 12s can be made substantially equal to the amount of metal diffused to the electrode layer WL on the top surface side thereof.

Furthermore, the width of the second slit 12s is wider than the width of the first slit 11s. Thus, it becomes easy to form a metal film on the inner wall of the first slit 11s through the second slit 12s. It is possible to form the sufficient amount of metal film on the lower layer side of the entire stacked body. Therefore, when the annealing of the metal silicide processing is performed, the amount of metal diffused to the inner wall of the first slit 11s can be made substantially equal to the amount of metal diffused to the inner wall of the second slit 12s. That is, it is possible to uniformly lower resistance in the stacking direction.

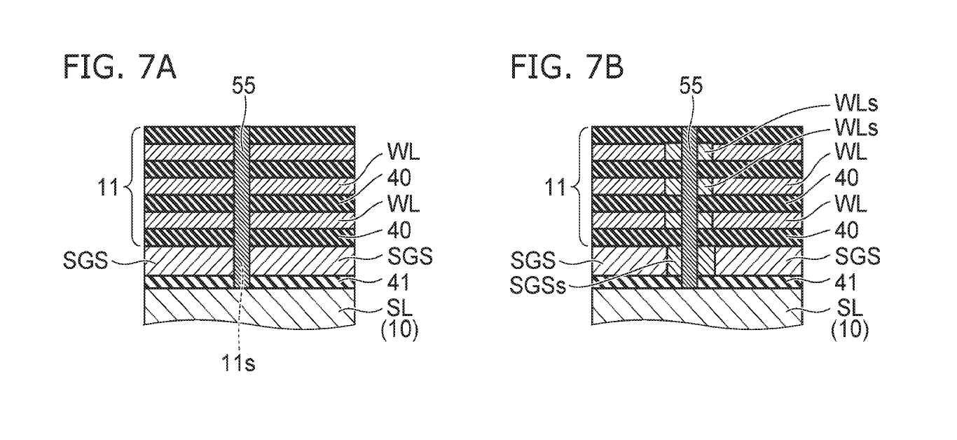

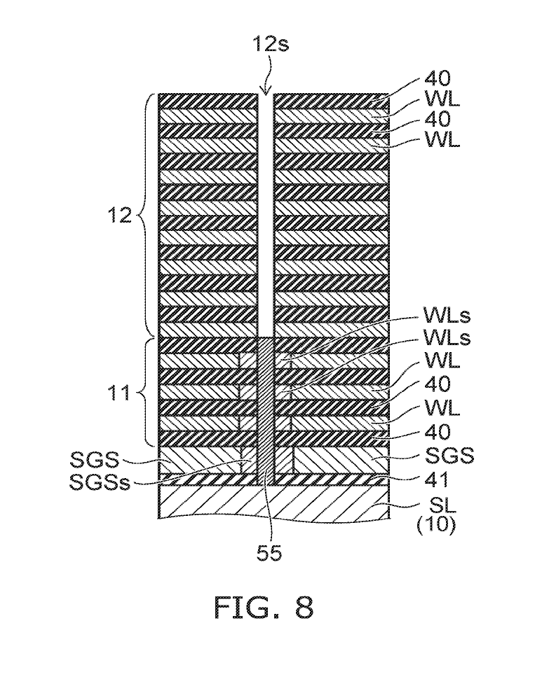

Next, another method for manufacturing a semiconductor memory device of the embodiment will be described with reference to FIG. 7A to FIG. 8.

As illustrated in FIG. 7A, the source-side select gate SGS is formed on the conductive layer SL with the insulating layer 41 disposed therebetween. On the source-side select gate SGS, there is formed the first stacked portion 11 in which the insulating layers 40 and the electrode layers WL are alternately stacked.

The first silt 11s is formed in the first stacked portion 11. The first slit 11s pierces the first stacked portion 11 in the stacking direction. The first slit 11s is formed by RIE using a mask (not illustrated), for example. The electrode layer WL and the source-side select gate SGS are each exposed on a sidewall of the first slit 11s.

The sacrificial film 55 is formed on the inner wall of the first slit 11s. The sacrificial film 55 is embedded in the first slit 11s. The side surface of the sacrificial film 55 is in contact with each of the electrode layer WL and the source-side select gate SGS. The sacrificial film 55 formed on the first stacked portion 11 is removed by CMP, for example.

For the sacrificial film 55, a material is used which has a high selectivity with respect to etching of the electrode layers WL and the insulating layers 40, and at least one of cobalt and nickel is used, for example.

As illustrated in FIG. 7B, the metal silicide portions WLs, SGSs are formed on the side surfaces of the electrode layer WL and the source-side select gate SGS that are in contact with the side surface of the sacrificial film 55. The metal silicide portions WLs, SGSs are formed by metal of the sacrificial film 55 being diffused to the electrode layer WL and the source-side select gate SGS when the above-described annealing of the metal silicide processing is performed.

As illustrated in FIG. 8, the second stacked portion 12 is formed on the first stacked portion 11. In the second stacked portion 12, the insulating layers 40 and the electrode layers WL are alternately stacked, similarly to the first stacked portion 11.

The second slit 12s is formed in the second stacked portion 12. The second slit 12s pierces the second stacked portion 12 to reach the sacrificial film 55. The second slit 12s is formed by RIE using a mask (not illustrated), for example. Here, the sacrificial film 55 is used as an etching stopper film. The top surface of the sacrificial film 55 is exposed on the bottom surface of the second slit 12s.

Here, as illustrated in FIG. 3B, the width of the bottom surface side of the second slit 12s is not more than the width of the top surface of the first slit 11s, and the width of the top surface side of the second slit 12s. The distance D1 is between the center 11c of the width of the first slit 11s and the center 12c of the width of the second slit 12s, and the distance D1 is not more than half the width of the first slit 11s.

Furthermore, the sacrificial film 55 has the high selectivity with respect to etching of the electrode layer WL and the insulating layer 40; over etching of second slit 12s can be available. Thus, a taper angle of the second slit 12s can be controlled by adjusting the amount of over etching in RIE. For example, the width of the bottom surface side of the second slit 12s may be substantially equal to the width of the top surface side thereof. The side surface of the second slit 12s can be made substantially perpendicular to a major surface of the conductive layer SL. Over etching after the second slit 12s reaches the sacrificial film 55 causes the width of the second slit 12s to be wider than the width of the first slit 11s, as illustrated in FIG. 13.

Thereafter, the silicide portions WLs of the electrode layers WL are formed on the side surfaces of the electrode layers WL in the second stacked portion 12, similarly to the above-described manufacturing method. A metal film (e.g., nickel, cobalt) is conformally formed on the sidewall of the second slit 12s, and is then annealed. Thus, the metal silicide portions WLs are formed on the electrode layers WL adjacent to the second slit 12s. This reduces resistance of the electrode layers WL.

Thereafter, an excess unreacted metal film is removed using a chemical solution containing sulfuric acid, for example. Here, the sacrificial film 55 formed on the first slit 11s is removed at the same time.

Subsequently, the insulating film 43 is formed on the inner walls of the first slit 11s and the second slit 12s, similarly to the above-described FIG. 6A and FIG. 6B. The intermediate layer ST illustrated in FIG. 3 is formed inner side of the insulating film 43. In this manner, the first separator 61 and the second separator 62 are integrally formed.

The drain-side select gate SGD is formed on the second stacked portion 12 with the insulating layer 40 disposed therebetween. The insulating layer 42 is formed on the drain-side select gate SGD.

Thereafter, the memory hole MH is formed in the insulating layer 42, the drain-side select gate SGD, the second stacked portion 12, the first stacked portion 11, and the source-side select gate SGS. The memory hole MH pierces from the insulating layer 42 to the source-side select gate SGS, and to reach the conductive layer SL.

Subsequently, each of the films illustrated in FIG. 3A is formed on the inner wall of the memory hole MH. Thereafter, a slit is formed extending through the insulating layer 42 and the drain-side select gate SGD to the insulating film 43, and the metal silicide portion SGDs of the drain-side select gate SGD. After the metal silicide portion SGDs of the drain-side select gate SGD is formed, the insulating film 43 and the intermediate layer ST are embedded in the inner wall of the slit, as illustrated in FIG. 2A.

Thereafter, the bit lines BL and the like are formed on the insulating layer 42. In this manner, the semiconductor memory device of this embodiment is obtained.

According to this embodiment, it is possible to reduce difficulty of the process for forming the slit, similarly to the above-described embodiment. Furthermore, it is possible to uniformly reduce resistance in the stacking direction.

In addition, according to this embodiment, the metal silicide processing is performed individually on the first stacked portion 11 and the second stacked portion 12. This makes it possible to reduce resistance in the stacking direction more uniformly than the above-described manufacturing method. The sufficient amount of metal film can be formed also on the lower layer side (bottom side) of the entire stacked body, and the metal silicide portion WLs can be securely formed on the electrode layer WL on the lower layer side with such a sufficient amount.

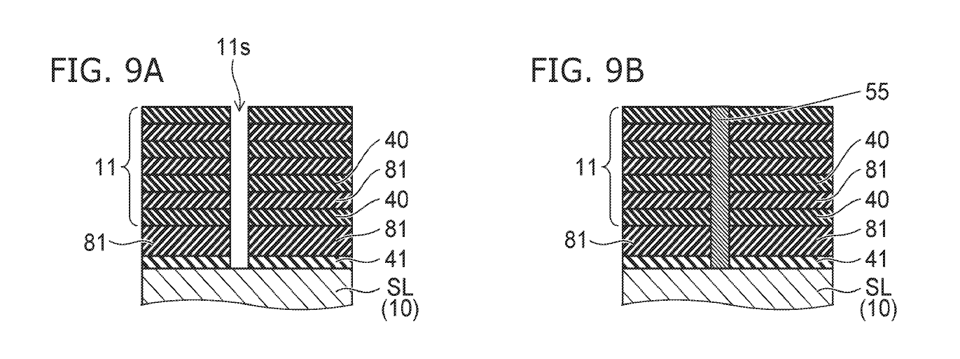

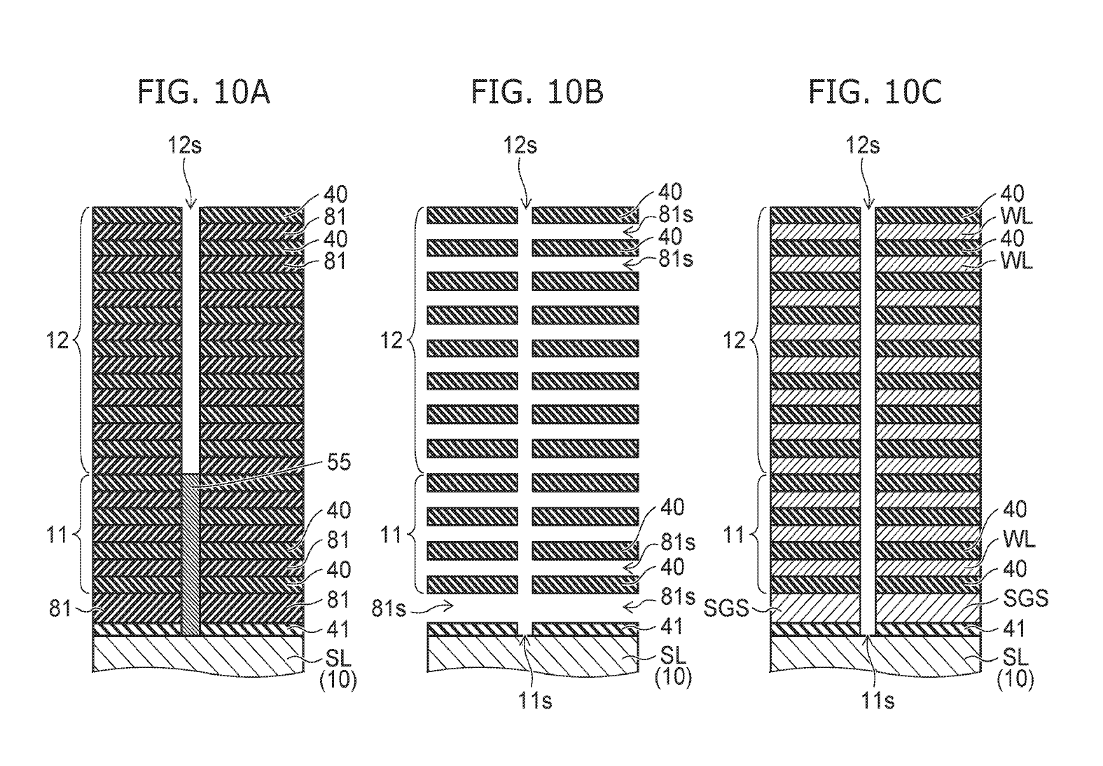

Next, further another method for manufacturing a semiconductor memory device of the embodiment will be described with reference to FIG. 9A to FIG. 10C.

As illustrated in FIG. 9A, a replacement member 81 is formed on the conductive layer SL with the insulating layer 41 disposed therebetween. On the replacement member 81, there is formed the first stacked portion 11 in which the insulating layers 40 and the replacement members 81 are alternately stacked. The replacement members 81 are layers that are replaced with the source-side select gate SGS and the electrode layers WL subsequently. The material of the replacement members 81 is selected from materials that are different from the insulating layers 40 and can provide etching selectivity with respect to the insulating layers 40. For example, silicon nitride is selected as the replacement members 81 in the case where silicon oxide is selected as the insulating layers 40.

The first slit 11s is formed in the first stacked portion 11. The first slit 11s pierces the first stacked portion 11 in the stacking direction. The first slit 11s is formed by RIE using a mask (not illustrated), for example.

As illustrated in FIG. 9B, the sacrificial film 55 is formed on the inner wall of the first slit 11s. The sacrificial film 55 is embedded in the first slit 11s. The sacrificial film 55 formed on the first stacked portion 11 is removed by CMP, for example. For the sacrificial film 55, a material is used which has a high selectivity with respect to etching of the electrode layers WL and the insulating layers 40.

As illustrated in FIG. 10A, the second stacked portion 12 is formed on the first stacked portion 11. In the second stacked portion 12, the insulating layers 40 and the electrode layers WL are alternately stacked, similarly to the first stacked portion 11.

The second slit 12s is formed in the second stacked portion 12. The second slit 12s pierces the second stacked portion 12 to reach the sacrificial film 55. The second slit 12s is formed by RIE using a mask (not illustrated), for example. Here, the sacrificial film 55 is used as an etching stopper film. The top surface of the sacrificial film 55 is exposed on the bottom surface of the second slit 12s.

Here, as illustrated in FIG. 3B, the width of the bottom surface side of the second slit 12s is not more than the width of the top surface of the first slit 11s, and the width of the top surface side of the second slit 12s. The distance D1 is between the center 11c of the width of the first slit 11s and the center 12c of the width of the second slit 12s, and the distance D1 is not more than half the width of the first slit 11s.

Furthermore, the sacrificial film 55 has the high selectivity with respect to etching of the electrode layer WL and the insulating layer 40; over etching of second slit 12s can be available. Thus, a taper angle of the second slit 12s can be controlled by adjusting the amount of over etching in RIE. For example, the width of the bottom surface side of the second slit 12s may be substantially equal to the width of the top surface side thereof. The side surface of the second slit 12s can be made substantially perpendicular to a major surface of the conductive layer SL. Over etching after the second slit 12s reaches the sacrificial film 55 causes the width of the second slit 12s to be wider than the width of the first slit 11s, as illustrated in FIG. 13.

As illustrated in FIG. 10B, the replacement member 81 is removed through the first slit 11s and the second slit 12s. Thus, spaces 81s are formed in portion of the replacement member 81 removed. As illustrated in FIG. 10C, the electrode layers WL and the source-side select gate SGS are formed in the spaces 81s. The electrode layers WL and the source-side select gate SGS are separated from each other.

Subsequently, the insulating film 43 is formed on the inner walls of the first slit 11s and the second slit 12s, similarly to the above-described FIG. 6A and FIG. 6B. The intermediate layer ST illustrated in FIG. 3 is formed inner side of the insulating film 43. In this manner, the first separator 61 and the second separator 62 are integrally formed.

The drain-side select gate SGD is formed on the second stacked portion 12 with the insulating layer 40 disposed therebetween. The insulating layer 42 is formed on the drain-side select gate SGD.

Thereafter, the memory hole MH is formed in the insulating layer 42, the drain-side select gate SGD, the second stacked portion 12, the first stacked portion 11, and the source-side select gate SGS. The memory hole MH pierces from the insulating layer 42 to the source-side select gate SGS, and to reach the conductive layer SL.

Subsequently, each of the films illustrated in FIG. 3A is formed on the inner wall of the memory hole MH. Thereafter, the bit lines BL and the like are formed on the insulating layer 42; the semiconductor memory device of this embodiment is obtained.

According to this embodiment, it is possible to reduce difficulty of the process for forming the slit, similarly to the above-described embodiment. Furthermore, it is possible to uniformly reduce resistance in the stacking direction.

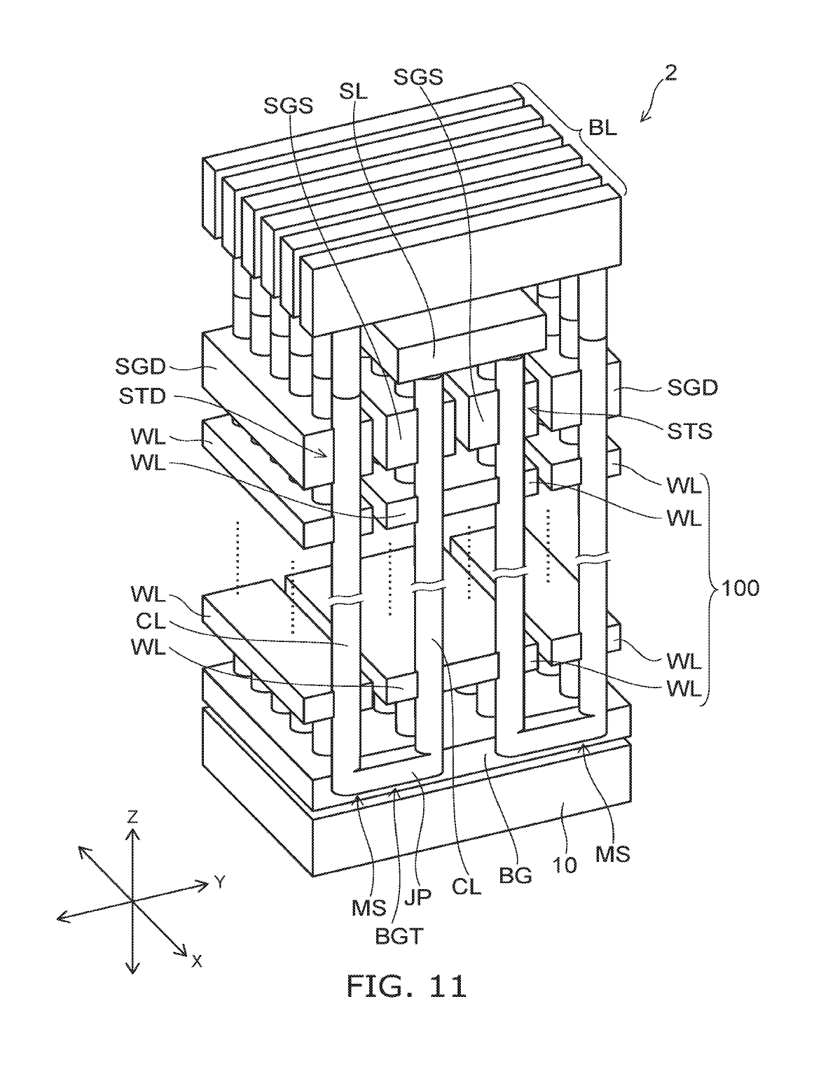

FIG. 11 is a perspective view schematically illustrating another example of a memory cell array 2 according to an embodiment of the semiconductor memory device. Note that, as in FIG. 1, for simplicity, elements such as the insulating layer are not illustrated in FIG. 11.

A back gate BG is provided on the conductive layer SL with an insulating layer disposed therebetween. On the back gate BG, the stacked body 100 is formed in which a plurality of electrode layers WL and a plurality of insulating layers 40 are alternately stacked.

A single memory string MS is formed in a U-shape and includes a pair of columns CL extending in the Z direction, and a connecting portion JP that connects the respective bottom ends of the pair of columns CL. The column CL is formed to be columnar or elliptic columnar, for example, and extends through the stacked body to the back gate BG.

A drain-side select gate SGD is provided on a top end of one of the pair of columns CL in the U-shaped memory string MS, and a source-side select gate SGS is provided on a top end of the other. The drain-side select gate SGD and the source-side select gate SGS are provided on the topmost electrode layer WL with the insulating layer 40 disposed therebetween.

The drain-side select gate SGD and the source-side select gate SGS are separated in the Y direction by the separator 60. The stacked body under the drain-side select gate SGD and the stacked body under the source-side select gate SGS are separated in the Y direction by the separator 60. That is, the stacked body between the pair of columns CL in the memory string MS is separated in the Y direction by the separator 60.

The intermediate layer ST is provided on the source-side select gate SGS with an insulating layer disposed therebetween. A plurality of bit lines (e.g., metal film) BL are provided on the drain-side select gate SGD and the intermediate layer ST with an insulating layer disposed therebetween. Each bit line BL extends in the Y direction.

Also in the memory cell array 2 illustrated in FIG. 11, a slit constituting the separator 60 in the stacked body 100 is formed so as to be divided into the first slit 11s and the second slit 12s, similarly to the above-described embodiment. When the second slit 12s is formed, in the first slit 11s, a film formed from a material having a high selectivity with respect to etching of the electrode layer WL and the insulating layer 40 is used. In this manner, it is possible to reduce difficulty of the process for forming the slit. Furthermore, it is possible to uniformly reduce resistance in the stacking direction.

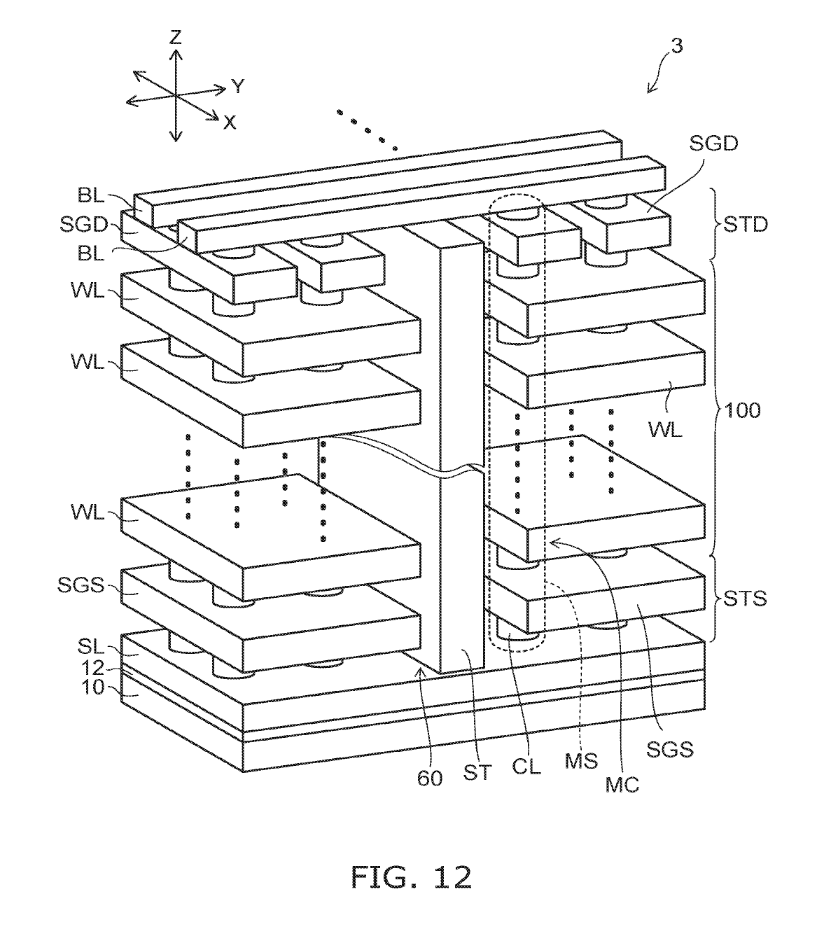

FIG. 12 is a perspective view schematically illustrating further another example of a memory cell array 3 according to an embodiment of the semiconductor memory device. Note that, as in FIG. 1, for simplicity, elements such as the insulating layer are not illustrated in FIG. 12.

As illustrated in FIG. 12, the conductive layer SL is provided on the substrate 10 with an insulating portion 12 disposed therebetween. The conductive layer SL is electrically connected with the bottom end of the channel body 20 illustrated in FIG. 3A and the bottom end of the intermediate layer ST illustrated in FIG. 3B.

Also in the memory cell array 3 illustrated in FIG. 12, a slit constituting the separator 60 in the stacked body 100 is formed so as to be divided into the first slit 11s and the second slit 12s, similarly to the above-described embodiment. When the second slit 12s is formed, in the first slit 11s, a film formed from a material having a high selectivity with respect to etching of the electrode layer WL and the insulating layer 40 is used. In this manner, it is possible to reduce difficulty of the process for forming the slit. Furthermore, it is possible to uniformly reduce resistance in the stacking direction.

The embodiment is not limited to the configuration in which the slit is formed in two separated phases, and the slit may be formed in three or more separated phases.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method for manufacturing a semiconductor memory device, comprising:
forming a first stacked portion on a conductive layer, the first stacked portion including a plurality of first layers and a plurality of second layers, the first layers separately stacked each other, the second layers provided between the first layers;
forming a first slit piercing the first stacked portion in a stacking direction of the first stacked portion;
forming a sacrificial film in the first slit;
forming a second stacked portion on the first stacked portion and the sacrificial film, the second stacked portion including the plurality of first layers and the plurality of second layers, the first layers separately stacked each other, the second layers provided between the first layers;
forming a second slit piercing the second stacked portion to reach the sacrificial film;
removing the sacrificial film through the second slit;
embedding a separation film into the first slit and the second slit;
forming a select gate on the second stacked portion; and
forming a plurality of memory cells in the first stacked portion and the second stacked portion, the forming the memory cells including
forming a hole piercing from the select gate to the first stacked portion,
forming a film including a charge storage film, on an inner wall of the hole, and
forming a channel body on an inner side of the film including the charge storage film.

2. The method according to claim 1, further comprising forming a metal silicide portion on the plurality of first layers exposed on sidewalls of the first slit and the second slit.

3. The method according to claim 1, further comprising forming an intermediate film on an inner wall of the first slit before the forming a sacrificial film.

4. The method according to claim 1, wherein a width of a bottom surface side of the second slit is not more than a width of a top surface of the first slit.

5. The method according to claim 1, wherein the plurality of first layers contain metal.

6. The method according to claim 1, wherein the sacrificial film contains at least one of nickel and cobalt.

7. The method according to claim 6, wherein the first layers contain silicon.

8. The method according to claim 7, further comprising forming a metal silicide portion containing at least one of nickel and cobalt on the plurality of first layers exposed on the sidewall of the first slit, after the forming a sacrificial film.

9. The method according to claim 1, wherein a width of a bottom surface side of the second slit is not more than a width of a top surface side of the second slit.

10. A semiconductor memory device comprising:
a conductive layer;
a first stacked portion provided on the conductive layer, the first stacked portion including a plurality of electrode layers and a plurality of insulating layers, the electrode layers separately stacked each other, the insulating layers provided between the electrode layers;
a first separator provided in the first stacked portion in a stacking direction of the first stacked portion;
a second stacked portion provided on the first stacked portion, the second stacked portion including the plurality of electrode layers and the plurality of insulating layers, the electrode layers separately stacked each other, the insulating layers provided between the electrode layers;
a second separator provided in the second stacked portion and being in contact with the first separator, a width of the second separator being not more than a width of the first separator; and
a column provided in the first stacked portion and the second stacked portion, the column including a channel body and a charge storage film, the channel body extending from an upper position of the second stacked portion to a lower position of the first stacked portion, the charge storage film provided between the channel body and the electrode layers of the first stacked portion, and between the channel body and the electrode layers of the second stacked portion.

11. The device according to claim 10, wherein a width of a bottom surface side of the second separator is not more than a width of a top surface side of the second separator.

12. The device according to claim 10, wherein
the first stacked portion includes a first metal silicide portion provided between the first separator and the electrode layers, and wherein
the second stacked portion includes a second metal silicide portion provided between the second separator and the electrode layers.

13. A semiconductor memory device comprising:
a conductive layer;
a first stacked portion provided on the conductive layer, the first stacked portion including a plurality of electrode layers and a plurality of insulating layers, the electrode layers separately provided each other and containing metal, the insulating layers provided between the electrode layers;
a first separator provided in the first stacked portion in a stacking direction of the first stacked portion, the first separator including a first film;
a second stacked portion provided on the first stacked portion, the second stacked portion including the plurality of electrode layers and the plurality of insulating layers, the electrode layers separately stacked each other, the insulating layers provided between the electrode layers;
a second separator provided in the second stacked portion and being in contact with the first separator, the second separator including a second film different from the first film, a width of the second separator being not more than a width of the first separator; and
a column provided in the first stacked portion and the second stacked portion, the column including a channel body and a charge storage film, the channel body extending from an upper position of the second stacked portion to a lower position of the first stacked portion, the charge storage film provided between the channel body and the electrode layers of the first stacked portion, and between the channel body and the electrode layers of the second stacked portion.

14. The device according to claim 13, wherein the first film contains a material having a higher selectivity with respect to etching of the electrode layers and the insulating layers than a material of the second film.

15. The device according to claim 13, wherein the electrode layers contain tungsten.

16. The device according to claim 13, wherein a width of a bottom surface side of the second separator is not more than a width of a top surface side of the second separator.
